(19) United States
(12) Patent Application Publication
(10) Pub. No.: US 2015/0275391 A1
(43) Pub. Date: Oct. 1, 2015

(54) HIGH PRESSURE REACTOR FOR SUPERCRITICAL AMMONIA

(71) Applicants: SIXPOINT MATERIALS, INC., Buellton, CA (US); SEOUL SEMICONDUCTOR CO., LTD., Seoul (KR)

(72) Inventor: Tadao HASHIMOTO, Santa Barbara, CA (US)

(21) Appl. No.: 14/676,281

(22) Filed: Apr. 1, 2015

Related U.S. Application Data
(60) Provisional application No. 61/973,359, filed on Apr. 1, 2014.

(51) Int. Cl. C30B 7/10; C30B 29/40

(52) U.S. Cl. CPC C30B 7/105; C30B 29/406

(57) ABSTRACT

A high-pressure cylindrical reactor suitable for a high-pressure process using supercritical ammonia to form bulk crystals of group III nitride or transition metal nitride is disclosed. In one instance, the reactor has a reactor body and lid formed of precipitation hardenable Ni—Cr superalloy and is sealed by a gasket made of Ni-based metal. Ni content of the gasket is greater than Ni content of both the reactor body and lid. The gasket is tapered so that its thickest part is at or near the gasket's inner radius or circumference, and the thinnest part of the gasket is more than 0.2 inch thick and is at or near the gasket's outer radius or circumference. The gasket's surfaces are compressed at 60,000 psi or higher. This construction provides a consistent seal of the reactor for repeated use.

### CROSS REFERENCE TO RELATED APPLICATIONS

This application claims the benefit of priority to U.S. patent application Ser. No. 61/973,359, entitled “High Pressure Reactor For Supercritical Ammonia,” filed Apr. 1, 2014 and naming as inventor Dr. Tadao Hashimoto. The contents of this application are incorporated by reference herein as if put forth in full below.

This application is also related to the following U.S. patent applications:

PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.0129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility Patent Application Ser. No. 60/973,602, filed on Sep. 19, 2007, by Tadao Hashimoto and Shuji Nakamura, entitled “GALLIUM NITRIDE BULK CRYSTALS AND THEIR GROWTH METHOD,” attorneys docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys docket number 30794.253-US-U1 (2007-774-2);

U.S. Utility Patent Application Ser. No. 61/067,117, filed on Feb. 25, 2008, and Ser. No. 12/392,960 filed Feb. 25, 2009, by Tadao Hashimoto, Edward Letts, Masanori Ikari, entitled “METHOD FOR PRODUCING GROUP III-NITRIDE WAFERS AND GROUP III-NITRIDE WAFERS,” attorneys docket number 62158-30002.00 or SIXPOI-003;

U.S. Utility Patent Application Ser. No. 61/058,900, filed on Jun. 4, 2008, and Ser. No. 12/455,760 filed Jun. 4, 2009, by Edward Letts, Tadao Hashimoto, Masanori Ikari, entitled “METHODS FOR PRODUCING IMPROVED CRYSTALLINITY GROUP III-NITRIDE CRYSTALS FROM INITIAL GROUP III-NITRIDE SEED BY AMMONOTHERMAL GROWTH,” attorneys docket number 62158-30004.00 or SIXPOI-002;

U.S. Utility Patent Application Ser. No. 61/058,910, filed on Jun. 4, 2008, and Ser. No. 12/455,683 filed Jun. 4, 2009 (now U.S. Pat. No. 8,236,267), by Tadao Hashimoto, Edward Letts, Masanori Ikari, entitled “HIGH-PRESSURE VESSEL FOR GROWING GROUP III NITRIDE CRYSTALS AND METHOD OF GROWING GROUP III NITRIDE CRYSTALS USING HIGH-PRESSURE VESSEL AND GROUP III NITRIDE CRYSTAL,” attorneys docket number 62158-30005.00 or SIXPOI-005;

U.S. Utility Patent Application Ser. No. 61/131,917, filed on Jun. 12, 2008, and Ser. No. 12/456,181 filed Jun. 12, 2009 (now U.S. Pat. No. 8,357,243) by Tadao Hashimoto, Masanori Ikari, Edward Letts, entitled “METHOD FOR TESTING III-NITRIDE WAFERS AND III-NITRIDE WAFERS WITH TEST DATA,” attorneys docket number 62158-30006.00 or SIXPOI-001;

U.S. Utility Patent Application Ser. No. 61/106,110, filed on Oct. 16, 2008 and U.S. Ser. No. 12/580,849 filed Oct. 16, 2009, by Tadao Hashimoto, Masanori Ikari, Edward Letts, entitled “REACTOR DESIGN FOR GROWING GROUP III NITRIDE CRYSTALS AND METHOD OF GROWING GROUP III NITRIDE CRYSTALS,” attorneys docket number SIXPOI-004;

U.S. Utility Patent Application Ser. No. 61/694,119, filed on Aug. 28, 2012, by Tadao Hashimoto, Edward Letts, Sierra Hoff, entitled “GROUP III NITRIDE WAFER AND PRODUCTION METHOD,” attorneys docket number SIXPOI-015;

U.S. Utility Patent Application Ser. No. 61/705,540, filed on Sep. 25, 2012, by Tadao Hashimoto, Edward Letts, Sierra Hoff, entitled “METHOD OF GROWING GROUP III NITRIDE CRYSTALS,” attorneys docket number SIXPOI-014;

which applications are all incorporated by reference herein in their entirety as if put forth in full below.

### BACKGROUND

1. Field of the Invention

The invention is related to a high-pressure reactor used to hold supercritical ammonia. The reactor is used to grow bulk crystal of group III nitride in supercritical ammonia. The reactor is also used to synthesize various metal nitride materials such as vanadium nitride, iron nitride, and titanium nitride. Group III nitride crystals are used to produce semiconductor wafers for various devices including optoelectronic devices such as light emitting diodes (LEDs) and laser diodes (LDs), and electronic devices such as transistors. More specifically, the group III nitride includes gallium.

2. Description of the Existing Technology

(Note: This patent application refers several publications and patents as indicated with numbers within brackets, e.g., [x]. A list of these publications and patents can be found in the section entitled “References.”)

Gallium nitride (GaN) and its related group III nitride alloys are the key material for various optoelectronic and electronic devices such as LEDs, LDs, microwave power transistors, and solar-blind photo detectors. Currently LEDs are widely used in displays, indicators, general illuminations, and LDs are used in data storage disk drives. However, the majority of these devices are grown epitaxially on heterogeneous substrates, such as sapphire and silicon carbide because GaN substrates are extremely expensive compared to these heteroepitaxial substrates. The heteroepitaxial growth of group III nitride causes highly defected or even cracked films, which hinder the realization of high-end optical and electronic devices, such as high-brightness LEDs for general lighting or high-power microwave transistors.

To solve fundamental problems caused by heteroepitaxy, it is indispensable to utilize crystalline group III nitride wafers sliced from bulk group III nitride crystal ingots. For the majority of devices, crystalline GaN wafers are favorable because it is relatively easy to control the conductivity of the wafer and GaN wafer will provide the smallest lattice/thermal mismatch with device layers. However, due to the high melting point and high nitrogen vapor pressure at elevated temperature, it has been difficult to grow GaN crystal ingots. Currently, the majority of commercially available GaN substrates are produced by a method called hydride vapor phase epitaxy (HVPE). HVPE is a vapor phase method, which has a difficulty in reducing dislocation density less than 10⁵ cm⁻².

To obtain high-quality GaN substrates of which dislocation density is less than 10⁵ cm⁻², a new method called ammonothermal growth has been developed [1-6]. Recently, high-quality GaN substrates having dislocation density less than 10⁵ cm⁻² can be obtained by the ammonothermal growth. However, due to high-pressure process, it is challenging to scale up the reactor for growth of large-sized crystals. In particular, sealing of the lid becomes unreliable when the inner diameter of the reactor becomes larger than 2 inch.

### SUMMARY OF THE INVENTION

The present invention discloses a high-pressure reactor and gasket suitable for a high-pressure process using supercritical ammonia. The reactor is suited to grow a bulk crystal of group III nitride and has a lateral dimension (e.g. diameter) greater than 2 inches. The reactor can instead synthesize various transition metal nitrides using supercritical ammonia. The reactor body has, for example, a cylindrical shape and is made of precipitation hardenable Ni—Cr based superalloy. The reactor has a lid made of precipitation hardenable Ni—Cr based superalloy on one end of the reactor body. The lid and body are in physical contact with a gasket made of Ni-based metal, and the Ni content of the gasket is higher than the Ni content of the precipitation hardenable Ni—Cr based superalloy of both the lid and reactor body. The gasket preferably contains more than 90% Ni and does not contain more than 10% copper. The gasket thickness may also decrease along the radial direction of the gasket so that the gasket is thinner at its outer radial edge than at its inner radial edge, and the thinnest part of the gasket is more than 0.2 inch thick. The gasket has sufficient compressive strength to withstand a compressive pressure of 60,000 psi or higher, and the gasket has a sufficiently high elastic limit or yield strength that the gasket can be reused at least 10 times before a replacement gasket is needed. This construction provides a consistent seal of the reactor for repeated use.

### BRIEF DESCRIPTION OF THE DRAWINGS

Referring now to the drawings in which like reference numbers represent corresponding parts throughout:

FIG. 1 is a schematic drawing of the high-pressure reactor. In the figure, each number represents the following:

1. High-pressure reactor body

2. Lid

3. Clamp having tapers that compliment tapers on the reactor body and lid

4. Gasket

5. Heater for lower zone

6. Heater for upper zone

7. Baffles

8. Nutrient basket

9. Nutrient

10. Seed crystals

11. Containment cell

12. Exhaust valve

13. Exhaust line

14. Valve operation device

15. Tapered shoulder or flange on the reactor body

16. Tapered shoulder or flange on the lid

17. Reactor's chamber

FIG. 2 is one example of a gasket. In the figure, each number represents the following:

21. Top view of the gasket

22. Cross section of the gasket

23. Inner edge of the gasket

24. Outer edge of the gasket

FIG. 3 has examples of cross-sections of gaskets and measurement of thinnest thickness and taper angle. In the figure, each number represents the following:

31. Basic design of a gasket

32. A gasket with both-side taper shown in profile

33. A gasket with a second taper on the outer edge

34. A gasket with a second taper on the inner edge

35. A gasket with a second and a third taper on the both edges

36. A gasket with a second taper on the outer edge which helps alignment

### DETAILED DESCRIPTION OF THE INVENTION

Overview

While the invention is not bound by this theory, the inventor theorizes that the invention is based in a technical finding that makes the reactor and gasket as described herein exceptionally well-suited to commercial manufacturing of large ingots of group III-nitride materials using an ammonothermal method. The inventor found that a gasket having decreasing thickness toward its outer periphery, having a thickness no less than 0.20 inch at its thinnest point, and being formed of a Ni-based alloy as described below provides a gasket that can be used in a high-pressure ammonothermal reactor at least 10 times without suffering mechanical or performance failure. While a skilled person would typically provide a softer gasket to maintain the high compressive force needed to seal the reactor, the inventor has been able to provide a harder gasket than the skilled person would typically use and also gain greater longevity for the gasket in an ammonothermal reactor. This set of properties is well beyond what a skilled person would think is possible from a pure nickel gasket or a conventional nickel alloy gasket.

The high-pressure reactor of this invention is designed to grow group III nitride crystals or to synthesize various transition metal nitride materials such as vanadium nitride, iron nitride and titanium nitride. Bulk crystals of group III nitride such as GaN can be grown in supercritical ammonia. Also, various metal nitride powders, nano-crystals, micro-crystals, and bulk crystals can be synthesized in supercritical ammonia. Crystal growth or material synthesis in supercritical ammonia is called ammonothermal process. In the ammonothermal process, high-pressure (1,000 psi˜60,000 psi) and high-temperature (300˜600° C.) ammonia is prepared in a high-pressure reactor. In particular, crystal growth of GaN typically requires pressure higher than 25,000 psi and temperature higher than 450° C. Currently, a high-pressure reactor of such pressure and temperature range is not commonly available. For example, Parr Instruments Company provides a high-pressure reactor that can hold up to 5000 psi at 500° C. with internal diameter of 3.25″. Another example is a High Pressure Equipment Company's high-pressure reactor that can reach 12,000 psi at 427° C. with internal diameter of 1″. A high-pressure reactor having inner diameter larger than 2″ which can reach 25,000 psi at temperature higher than 450° C. requires a specialized technology. Since, the structure of the high-pressure reactor must withstand such pressure and temperature, it is typically constructed with precipitation hardenable Ni—Cr based superalloys.

In addition, typical ammonothermal process requires a chemical additive called a mineralizer to enhance the reaction. For example, bulk growth of GaN typically requires alkali metal mineralizers such as lithium, sodium or potassium, or halide mineralizer such as ammonium fluoride, ammonium chloride, ammonium bromide, or ammonium iodide. Alkali metal mineralizer creates basic supercritical ammonia whereas halide mineralizer creates acidic supercritical ammonia. In either case, the reactor material must be carefully selected to avoid corrosion by the supercritical ammonia. In the case of basic ammonia, precipitation hardenable Ni—Cr based superalloy can be used as disclosed in U.S. Utility Patent Application Ser. No. 61/058,910. When acidic ammonia is used, precipitation hardenable Ni—Cr based superalloy is corroded, thus appropriate lining made of Pt-based material is used as disclosed in Japanese Patent Application (P2005-4998, publication number JP2009-193355) Lining can also be used to reduce impurities in basic ammonia.

To grow large-scale bulk crystals or to increase productivity of metal nitride materials, it is necessary to develop large-scale high-pressure reactor having inner diameter more than 2 inch. One type of high-pressure reactor for ammonothermal growth is disclosed in U.S. Pat. No. 8,871,024. However, this construction often utilizes an internal capsule to isolate corrosive supercritical ammonia and to utilize low-carbon steel or stainless steel rather than precipitation hardenable Ni—Cr superalloy for the reactor material. Due to the complicated capsule design, the reliability of the reactor gasket is not sufficient. Also, there is no guarantee that the gasket can be used for more than once.

A simpler reactor design using precipitation hardenable Ni—Cr superalloy is disclosed in U.S. Pat. No. 8,236,267. However, sealing the high-pressure reactor is quite challenging in such large-scale ammonothermal high-pressure reactor. Through our dedicated research on gasket design including material choice, we discovered that a precise design of the shape as well as selection of material is needed to achieve reliable and repeatable seal.

Technical Description of the Invention

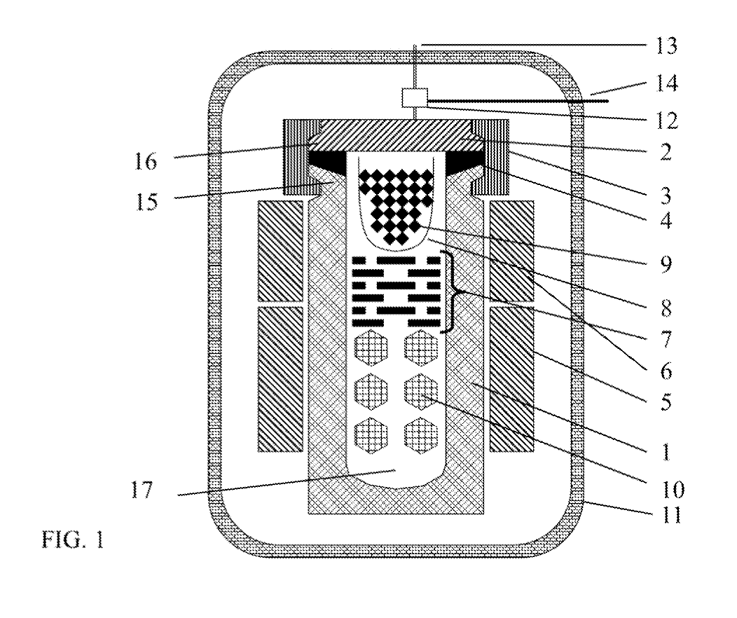

FIG. 1 illustrates a high-pressure reactor of this invention. The high-pressure reactor body 1 has a cylindrical shape and is made of precipitation hardenable Ni—Cr based superalloy. The high-pressure reactor body has an opening on one end and optionally a second opening at its opposite end so that internal components including source material, seed crystals, and baffles can be installed. The high-pressure reactor has at least one lid 2 made of precipitation hardenable Ni—Cr based superalloy at an end. The lid 2 is sealed with a gasket 4 made of Ni-based metal having an ultimate tensile strength in the range of 50-100 ksi and a Ni content that is greater than the nickel content of the body's precipitation hardenable Ni—Cr based superalloy, or preferably greater than 90%. Also, the gasket material preferably contains little or no copper. The copper content may be less than 10% or, more preferably, less than 1%. As disclosed in U.S. Pat. No. 8,236,267, a closing mechanism for the high-pressure reactor having inner diameter larger than 2″ is preferably a clamp type closure 3 rather than a screw type closure. The reactor body 1 and the lid 2 each have a shoulder or flange (15 and 16, respectively) so that clamp 3 can push the reactor body and lid toward one another and against gasket 4 to seal the reactor's chamber 17 from its ambient during use. The clamp is typically split into two or three sections, and each section is connected with bolts. The number of bolts is preferably at least 2 for each joint, i.e. if the clamp is split into three sections, a total of 6 or more bolts is preferably used. When the bolts are tightened, gaps between the clamp sections are narrowed so that the diameter of the clamp reduces. The reactor body shoulder 15, lid shoulder 16, and inner contacting surfaces of the clamp 3 that contact the reactor body shoulder and lid shoulder are preferably tapered, so that the clamp presses upon and squeezes the reactor body shoulder and lid shoulder together as the clamp is tightened and the clamp diameter decreases. The tapered shoulders on the reactor body and lid and the tapered, contacting inner surfaces of the clamp transfer the radial force to vertical force so that the gasket is compressed. The angle of taper is selected to provide the compressive force needed to draw the reactor body and lid together and compress the gasket a sufficient amount to fully close the reactor, so that the contents of the reactor do not leak from within it during operation. To obtain necessary compression to seal the gasket, hydraulic wrenches are preferably used. In addition, it is desirable to tighten all bolts simultaneously by using multiple hydraulic wrenches so that the reactor body and lid shoulders are drawn together evenly about each shoulder's circumference.

When group III nitride is grown in the high-pressure reactor 1, the chamber 17 of the high-pressure reactor 1 is divided into at least two regions with baffles 7. A source material called nutrient 9 is held in a nutrient basket 8 located in the upper dissolution region. Seed crystals 10 are located in the lower crystallization region. The high-pressure reactor is heated with external heaters 5 and 6. To mitigate potential hazard of reactor rupture, the entire system is enclosed in a containment cell 11. The heater temperature is controlled from the outside of the containment cell. Ammonia within the reactor's chamber can be released to the exhaust line 13 by opening the exhaust valve 12 from outside of the containment cell 11 via a valve operation device 14. The valve operation device can utilize mechanical means, pneumatic means, or electromagnetic means.

The gasket of this invention is intended to be used many times, at least 10 times. To achieve a reliable seal for a high-pressure reactor having an inner diameter (ID) larger than 2″, the high-pressure reactor in the present invention utilizes a Ni-based gasket having moderate strength. The typical ultimate tensile strength of the precipitation hardenable Ni—Cr superalloy used to make the reactor body, lid, and/or clamps is more than 150 ksi at room temperature. To attain a suitable deformation necessary to seal the reactor multiple times, the ultimate tensile strength of the gasket material is within the range of 50-100 ksi at room temperature. This value is higher than the tensile strength of copper alone (30-50 ksi at room temperature), which is more commonly used as a gasket material.

To achieve a reliable seal for a high-pressure reactor having an ID larger than 2″, the Ni-based gasket has a Ni content greater than that of the reactor material or preferably greater than 90%, more preferably at least 99%. Also, the copper content of the gasket is preferably 10% or less, preferably less than 1%, more preferably less than 0.5%, and in some embodiments, less than 0.3% or less than or equal to about 0.25%. Ni alloy 200 is one example of a material that can be used to form a gasket. Ni alloy 200 has a nickel content of 99.0% or more and copper content of 0.25% or less. The gasket can be used repeatedly for at least 10 times by maintaining the thinnest part of the gasket 4 to be greater than 0.2 inch thick and having the gasket 4 tapered along its radial direction. In the case of GaN crystal growth, the gasket surface is compressed at 60,000 psi or higher in order to hold an operating pressure of over 25,000 psi at a temperature greater than 450° C. The compression force to seal the surfaces of reactor lid and body to the gasket can be attained by utilizing a clamp 3, or other mechanisms such as a screw lid in which a lid is clamped to a reactor body by screws passing through the lid and engaging with threads in the body. The high compression force can be obtained by using hydraulic wrench. A gasket that tapers from its thicker point along the inner circumference or radius of the gasket towards a thinner point at or near the outer circumference or radius allows part of the compression force to be applied towards outer radial direction, enabling self-sealing of the mating surface between the gasket and the reactor body, and between the gasket and the lid. Unlike typical gaskets for vacuum seal, the gasket preferably does not have a knife edge design because an indentation caused by the knife edge becomes a leak path during the next use of the gasket. A knife edge-type gasket is typically for one time use. Typically, a high-pressure gasket for an ammonothermal reactor is designed for one-time use because of extremely high compression force applied to the lid and reactor body. By using a soft material which deforms well, the gasket changes its shape to fit the sealing surface of the high-pressure reactor body and the lid, thus sealing the high-pressure fluid well. However, if the gasket deforms too much, it can only be used for one time because it loses the original shape.

To attain the moderate deformation needed to seal the reactor for multiple times, the gasket material has higher Ni concentration than the material of the high-pressure reactor and/or lid. To hold high-pressure at high temperature needed in the ammonothermal process, the high-pressure reactor and/or lid is typically constructed with precipitation hardenable Ni—Cr superalloys such as R-41, I-720, I-718, I-706 and/or Waspalloy. The typical Ni content of R41, I-720, I-718, I-706 and Waspalloy is 54%, 57%, 53%, 42% and 58%, respectively. Therefore, the gasket's Ni concentration is higher than these values, or preferably higher than 90%, more preferably at least 99%. Sometimes the material for the high-pressure reactor and the material for the lid are different. In such case, the Ni content of the gasket is higher than the maximum Ni content of either the reactor body or lid. The copper content is preferably less than 10%, and more preferably no more than 1%. Elimination of copper from the gasket material is important for maintaining the ultimate tensile strength and corrosion resistance of the gasket needed for ammonothermal applications.

Due to the high compression pressure, the gasket slightly deforms and becomes thinner. To avoid an ammonia leak by cracking and/or too much thinning of the gasket, the thinnest part of the gasket 4 is preferably more than 0.2 inches. The thinnest part of the gasket is defined as the minimum distance from one side to the other side of the disk-shaped gasket. As explained in the Examples below, we discovered that this minimum thickness is needed for repeated and reliable use of the gasket. When the gasket is too thick, however, the gasket may rupture outward due to internal pressure. Thus, the gasket thickness is preferably greater than or equal to about 0.2 inches and less than or equal to about 1 inch, more preferably greater than or equal to about 0.2 inches and less than or equal to about 0.5 inch, and in another embodiment, gasket thickness is as close to the minimum thickness as practical.

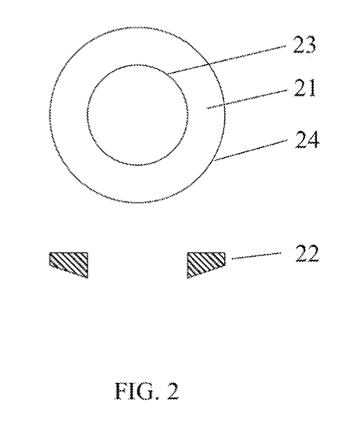

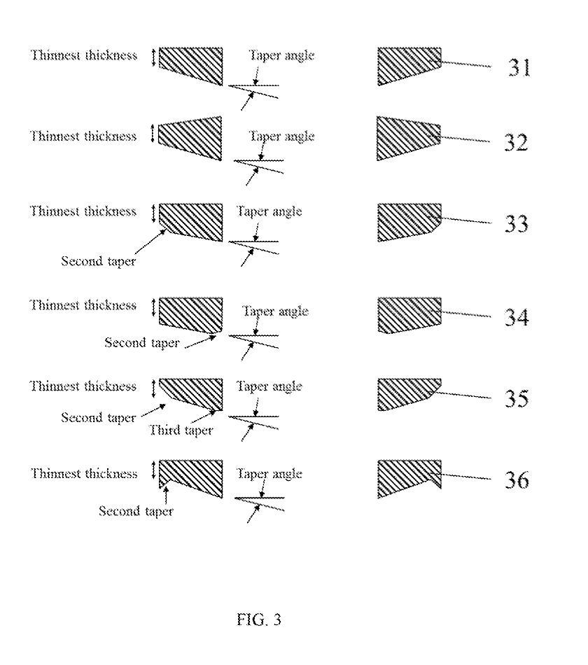

FIG. 2 shows one example of the gasket. The top view of the gasket 21 shows how the gasket has an annular shape with inner circumference or radius at inner edge 23 and outer circumference or radius at outer edge 24. As shown in the cross-sectional view 22, the gasket is tapered from the gasket's inner radius or circumference and toward the outer radial direction. In this case, the taper is on a gasket surface that engages the reactor body. The angle of taper as measured to a horizontal line drawn through the horizontal gasket is between 10 degrees and 23 degrees for the gasket depicted in FIG. 2, and the taper angle is preferably between 15 degrees and 20 degrees. Although a conventional gasket for a high-pressure reactor has either no taper angle (0 degrees) on either surface or a high taper angle (over 23 degrees) on at least one surface, as disclosed in U.S. Pat. No. 8,871,024, U.S. Pat. No. 8,236,237 or Japanese Patent Application publication number JP2006-193355 (also published as US2009013926), the gaskets designed for these high-pressure reactors are not suitable for repeated use due to too much deformation of the gasket. In FIG. 2, the thinnest part of the gasket is the outer most thickness of the gasket. FIG. 3 shows a few examples of various designs with location of thinnest part and taper angle measurement. The gasket can have taper on both surfaces as shown in FIG. 3 (gasket 32). If both surfaces taper, the angles of each taper can be same (i.e. symmetrical) or different (asymmetrical). In this case, the taper angle to the horizontal line is between 10 degrees and 23 degrees, preferably between 15 degrees and 20 degrees, for either or both surfaces.

The gasket can have a second and optionally a third taper angle in addition to the primary taper angle as shown in FIG. 3 (see gaskets 33, 34, 35 and 36). These second and third tapers have an effect of reducing crack formation due to gasket deformation. If the second taper is on the inner edge, the taper angle is preferably larger than that of the first taper angle. If the second taper is on the outer edge, the taper angle is preferably smaller than that of the first taper angle. The gasket can optionally have both inner and outer tapers in addition to the primary gasket taper.

In FIG. 3, gasket 36 has a second taper angle on the outer edge which acts as an alignment guide so that the gasket is aligned easily to the high-pressure reactor body or lid. In this case, the thinnest part does not correspond to the outer most point. The alignment guide can be located at the inner edge. In either case, the alignment guide is characterized as a bump along the outer circumference of the gasket.

The gasket construction explained above provides a consistent seal of the reactor for repeated use for at least 10 times.

### Example 1

### Gasket Compression Test

A cylindrical high-pressure reactor having inner diameter more than 2″, made of precipitation hardenable Ni—Cr superalloy has a cylindrical reactor body that is open on both ends. The lids for each end are made of another type of precipitation hardenable Ni—Cr superalloy. The gasket is made of Ni-based alloy having Ni content higher than 99%. The gasket material contains up to 1% of copper. The gasket had second and third taper angles in addition to the primary taper angle (FIG. 3 gasket 35). The primary taper angle was 18 degrees, the inner taper at the gasket's inner circumference was 8 degrees, and the outer taper at the gasket's outer circumference was 31.31 degrees. The thickness at the thinnest part (at the gasket's outer edge) was 0.195″. Two gaskets were used to seal the lids, one on each end. Before closing the lid, water was added to conduct a pressurization test with water.

When the lids were sealed by tightening the bolts of the clamps at 1,278 ft-lb, the gasket compression pressure was estimated to 46,950 psi. With this setting, the vapor leaked out from the gasket when the reactor was heated to 600° C. to produce pressure within the reactor that was calculated to be about 13,600 psi.

When the lids were sealed by tightening the bolts of the clamps at 1,592 ft-lb, the gasket compression pressure was estimated to be 58,520 psi. With this setting, the vapor leaked out from the gasket when the reactor was heated to 600° C. and was self-pressurized at about 21,000 psi.

When the lids were sealed by tightening the bolts of the clamps at 1,719 ft-lb, the gasket compression pressure was estimated to be 63,151 psi. With this setting, the reactor held the pressure of 34,000 psi when the reactor was heated to 600° C.

From these experiments, we concluded that a high-pressure reactor using a gasket as disclosed herein having a Ni content greater than 90% requires a compression pressure greater than approximately 60,000 psi to hold a pressure of 24,000 psi or more at a temperature between 450 to 600° C.

As discussed above, the smallest thickness of this gasket was 0.195″. The next two examples demonstrate that a gasket having this thickness is usable for a limited number of times but is not sufficient for extended, repeated use.

### Example 2

### Thinner Gasket Design

The same reactor, lids and gaskets were used to create high-pressure ammonia at high temperature. This time, GaN crystals were actually grown in the reactor. The reactor was divided into two regions with baffles. Polycrystalline GaN nutrient was placed in the upper region and seed crystals were placed in the lower region. Alkali metal-based mineralizer was added to the ammonia in the high-pressure reactor.

The gaskets of the same design as ones in Example 1 were used to seal the high-pressure reactor. The tightening torque was 1,719 ft-lb, which provided more than 60,000 psi compression pressure to the gasket's surfaces. Although the first crystal growth run was successful without leakage of ammonia, the repeated use of these gaskets resulted in leakage of ammonia at growth condition (pressure between 20,000 to 30,000 psi and temperature between 450 to 600° C.).

### Example 3

### Gasket of Current Invention

The same high-pressure reactor and lids were used to grow GaN crystals. In this example, the gaskets had the same taper angles as the gaskets in Example 1 and Example 2. The minimum thickness was 0.255″ and was located at the outer edge of the gaskets. Similar to the procedure in Example 2, GaN crystals were grown. The tightening torque was 1,783 ft-lb, which provided more than 60,000 psi compression. The gaskets of this example perform much better than the gaskets of Example 2.

With this setting, these gasket could be used repeatedly without leakage from the gasket. Although the gaskets were slightly thinned from the compression, they could hold the high-pressure ammonia for more than 10 times or cycles of use in the high-pressure reactor, which operates in batch mode due to the high pressure. From these experiments, we concluded that the gasket requires minimum thickness of approximately 0.2″. As demonstrated here, slight change in the gasket thickness can make a significant improvement in gasket performance.

Advantages and Improvements

A high-pressure reactor of this invention comprises a high-pressure reactor and lid(s) made of precipitation hardenable Ni—Cr superalloy and gasket of which ultimate tensile strength is preferably in the range of 50-100 ksi. The Ni content of the gasket is greater than the Ni content of the precipitation harden able Ni—Cr superalloy, or preferably greater than 90% or more and, more preferably, greater than 99%. Greater Ni content makes the gasket soft enough to ensure reliable seal of the lid(s). In addition, using a Ni or Ni-based alloy with less than 1% copper makes the gasket hard enough for repeated use. Due to the high-compression pressure needed to seal the lid, the gasket deforms and becomes thinner during use. Precise control of thickness and taper angle is therefore advised to obtain desired performance of the gasket over many reactor cycles. By maintaining the minimum thickness of the gasket greater than 0.2″, the gasket of the current invention can avoid leakage even after thinning occurs due to gasket compression. An advantage of this invention is extended lifetime of the gasket and optionally a reduction of tightening torque needed to reliably seal the lid and reactor body. All of these advantage contributes to lower cost manufacturing of metal nitride materials by the ammonothermal process.

Possible Modifications

Although the preferred embodiment describes gasket having Ni content higher than 90%, the same benefits can be expected as long as the Ni content is higher than that of the precipitation hardenable Ni—Cr superalloy used to construct the reactor body and/or lid. When a gasket has a lower Ni content than both the lid and the reactor body, the compression pressure needed to effectively seal the reactor during use would be higher due to the gasket's greater hardness.

Although the preferred embodiment describes gaskets of a certain design, the same benefits can be expected with different design as long as (a) the gasket is tapered down from the inner radius or circumference in a radial direction toward the outer radius or circumference of the gasket, (b) the thinnest part of the gasket is more than 0.2″, and/or (c) the primary taper angle of the gasket to the horizontal plane is between 1 and 45 degrees. Also, the gasket may not have a second or third taper.

A transition metal nitride may be formed using a method as disclosed in e.g. U.S. Pat. No. 8,920,762 (entitled “Synthesis Method Of Transition Metal Nitride And Transition Metal Nitride”) or in U.S. Pat. No. 8,971,018 (entitled “Ultracapacitors Using Transition Metal Nitride-Containing Electrode And Transition Metal Nitride”), each of which is incorporated by reference herein as if put forth in full below.

Consequently, the invention, by way of example and not by way of limitation on the scope of the invention, provides the following:
1. A cylindrical high-pressure reactor for a process using supercritical ammonia comprising
   (a) a main body having an annular cross-section and made of precipitation hardenable Ni—Cr based superalloy, having its longest dimension along the vertical direction, its inner diameter larger than 2 inches, its minimum outer diameter larger than 4 inches, and its minimum wall thickness larger than 1 inch;
   (b) at least one lid on an end of the main body;
   (c) a gasket to seal the lid to the main body, wherein the gasket has an annular cross-section with an inner radius and an outer radius, and the gasket comprises a Ni-based metal with a Ni content greater than a Ni content of the body's precipitation hardenable Ni—Cr based superalloy;
   (d) the gasket's Ni-based metal has an ultimate tensile strength between 50 and 100 ksi at room temperature; and
   (e) a first major surface of the gasket tapers so that the gasket has a thicker portion at the inner radius and a thinner portion toward the outer radius, and wherein the gasket when positioned horizontally has a first taper forming an angle to a horizontal plane of about 10 to about 23 degrees.
2. A reactor according to paragraph 1, wherein the gasket has a minimum thickness of at least 0.2″.
3. A reactor according to paragraph 1 or paragraph 2 wherein the first taper angle of the gasket to the horizontal plane is between 1 degree and 45 degrees and optionally is between 15 degrees and 20 degrees.
4. A reactor according to any one of paragraphs 1 through 3 wherein the gasket is compressed between the lid and the main body at a pressure greater than 60,000 psi.
5. A reactor according to any one of paragraphs 1 through 4 wherein the Ni content of the gasket is greater than 90%.
6. A reactor according to paragraph 5 wherein the Ni content of the gasket is greater than 99%.
7. A reactor according to any one of paragraphs 1 through 5 wherein the gasket has a Cu content of less than 10%.
8. A reactor according to any one of paragraphs 1 through 6 wherein the gasket has a Cu content of less than 1%.
9. A reactor according to paragraph 8 wherein the gasket has a Cu content of less than 0.5%.
10. A reactor according to paragraph 9 wherein the gasket has a Cu content of less than or equal to about 0.25%.
11. A reactor according to any one of paragraphs 1 through 10 wherein the gasket has a second taper along an outer edge of the gasket, and the second taper has an angle to the horizontal plane that is greater than the first taper angle.
12. A reactor according to any one of paragraphs 1 through 10 wherein the gasket has a second taper along an outer edge of the gasket to provide an alignment guide to the gasket.
13. A reactor according to any one of paragraphs 1 through 10 wherein the gasket has a second taper along an inner edge of the gasket, and the second taper has an angle to the horizontal plane that is less than the first taper angle.
14. A reactor according to any one of paragraphs 1 through 10 wherein the gasket has a second taper along an inner edge of the gasket, and the second taper has an angle to the horizontal plane that is greater than the first taper angle and in an opposite direction to the first taper to provide an alignment guide to the gasket.
15. A reactor according to any one of paragraphs 11 through 14 wherein the first taper angle and the second taper angle are both on the first major surface of the gasket.
16. A reactor according to any one of paragraphs 11 through 15 wherein the gasket has a third taper that has an angle to the horizontal plane different from the first taper's angle and the second taper's angle, and the third taper is on a different edge of the gasket than the second taper angle.
17. A reactor according to paragraph 16 wherein the third taper is on the first major surface of the gasket.
18. A reactor according to paragraph 16 or paragraph 17 wherein the angle of the third taper is 0°.
19. A reactor according to any paragraph above wherein the gasket has a second major surface that is flat and has an angle of 0° to the horizontal plane.
20. A reactor according to any one of paragraphs 1 through 18 wherein the second major surface has an angle to the horizontal plane that is not 0°.
21. A reactor according to any paragraph above wherein the gasket is thinner at its outer radial edge than at its inner radial edge.
22. A reactor according to any one of paragraphs 1 through 21 wherein the high-pressure reactor is configured for use in growing group III nitride crystals in supercritical ammonia.
23. A reactor according to paragraph 22, wherein the group III nitride is GaN.
24. A gasket as provided in any paragraph above.
25. A method comprising heating an exterior portion of the reactor of any one of paragraphs 1 through 23 at a temperature of at least 500° C. and using supercritical ammonia having a pressure greater than 20,000 psi to form crystalline group III nitride.
26. A method according to paragraph 25 wherein the crystalline group III nitride is a single crystal of said group III nitride having a lateral size greater than 2 inches.
27. A method according to paragraph 25 or paragraph 26, wherein the group III nitride is GaN.
28. A method comprising heating an exterior portion of the reactor of any one of paragraphs 1 through 23 and using supercritical ammonia to form a transition metal nitride.

### REFERENCES

The following references are also incorporated by reference herein:
[1] R. Dwilinski, R. Doradzinski, J. Garczynski, L. Sierzputowski, Y. Kanbara, U.S. Pat. No. 6,656,615.
[2] R. Dwilinski, R. Doradzinski, J. Garczynski, L. Sierzputowski, Y. Kanbara, U.S. Pat. No. 7,132,730.
[3] R. Dwilinski, R. Doradzinski, J. Garczynski, L. Sierzputowski, Y. Kanbara, U.S. Pat. No. 7,160,388.
[4] K. Fujito, T. Hashimoto, S. Nakamura, International Patent Application No. PCT/US2005/024239, WO07008198.
[5] T. Hashimoto, M. Saito, S. Nakamura, International Patent Application No. PCT/US2007/008743, WO07117689. See also US20070234946, U.S. application Ser. No. 11/784,339 filed Apr. 6, 2007.
[6] D′ Evelyn, U.S. Pat. No. 7,078,731.

Each of the references discussed in this document is incorporated by reference in its entirety as if put forth in full herein, and particularly with respect to reactor design and components, description of methods of making using ammonothermal methods, and methods of using gallium nitride substrates.

What is claimed is:

1. A cylindrical high-pressure reactor for a process using supercritical ammonia comprising
(a) a main body having an annular cross-section and made of precipitation hardenable Ni—Cr based superalloy, having its longest dimension along the vertical direction, its inner diameter larger than 2 inches, its minimum outer diameter larger than 4 inches, and its minimum wall thickness larger than 1 inch;
(b) at least one lid on an end of the main body;
(c) a gasket to seal the lid to the main body, wherein the gasket has an annular cross-section with an inner radius and an outer radius, and the gasket comprises a Ni-based metal with a Ni content greater than a Ni content of the body's precipitation hardenable Ni—Cr based superalloy;
(d) the gasket's Ni-based metal has an ultimate tensile strength between 50 and 100 ksi at room temperature; and
(e) a first major surface of the gasket tapers so that the gasket has a thicker portion at the inner radius and a thinner portion toward the outer radius, and wherein the gasket when positioned horizontally has a first taper forming an angle to a horizontal plane of about 10 to about 23 degrees.

2. A reactor according to claim 1 wherein the gasket has a minimum thickness of at least 0.2″.

3. A reactor according to claim 1 wherein the first taper angle of the gasket to the horizontal plane is between 15 degrees and 20 degrees.

4. A reactor according to claim 1 wherein the gasket is compressed between the lid and the main body at a pressure greater than 60,000 psi.

5. A reactor according to claim 1 wherein the Ni content of the gasket is greater than 90%.

6. A reactor according to claim 5 wherein the Ni content of the gasket is greater than 99%.

7. A reactor according to claim 1 wherein the gasket has a Cu content of less than 10%.

8. A reactor according to claim 1 wherein the gasket has a Cu content of less than 1%.

9. A reactor according to claim 1 wherein the gasket has a second taper along an outer edge of the gasket and on the same major surface as the first taper, and the second taper has an angle to the horizontal plane that is greater than the first taper angle.

10. A reactor according to claim 1 wherein the gasket has a second taper along an outer edge of the gasket and on the same major surface as the first taper to provide an alignment guide to the gasket.

11. A reactor according to claim 1 wherein the gasket has a second taper along an inner edge of the gasket and on the same major surface as the first taper, and the second taper has an angle to the horizontal plane that is less than the first taper angle.

12. A reactor according to claim 1 wherein the gasket has a second taper along an inner edge of the gasket and on the same major surface as the first taper, and the second taper has an angle to the horizontal plane that is greater than the first taper angle and in an opposite direction to the first taper to provide an alignment guide to the gasket.

13. A reactor according to claim 9 wherein the gasket has a third taper that has an angle to the horizontal plane different from the first taper's angle and the second taper's angle and is on the same major surface as the first taper, and the third taper is on a different edge of the gasket than the second taper angle.

14. A reactor according to claim 10 wherein the gasket has a third taper that has an angle to the horizontal plane different from the first taper's angle and the second taper's angle and is on the same major surface as the first taper, and the third taper is on a different edge of the gasket than the second taper angle.

15. A reactor according to claim 11 wherein the gasket has a third taper that has an angle to the horizontal plane different from the first taper's angle and the second taper's angle and is on the same major surface as the first taper, and the third taper is on a different edge of the gasket than the second taper angle.

16. A reactor according to claim 12 wherein the gasket has a third taper that has an angle to the horizontal plane different from the first taper's angle and the second taper's angle and is on the same major surface as the first taper, and the third taper is on a different edge of the gasket than the second taper angle.

17. A reactor according to claim 15 wherein the angle of the third taper is 0°.

18. A reactor according to claim 16 wherein the angle of the third taper is 0°.

19. A reactor according to claim 1 wherein the gasket has a second major surface that is flat and has an angle of 0° to the horizontal plane.

20. A reactor according to claim 1 wherein the gasket has a second major surface at an angle to the horizontal plane that is not 0°.

21. A reactor according to claim 1 wherein the gasket is thinner at its outer radial edge than at its inner radial edge.

22. A reactor according to claim 1 wherein the high-pressure reactor is configured for use in growing group III nitride crystals in supercritical ammonia.

23. A reactor according to claim 22, wherein the group III nitride is GaN.
